(19) United States
(12) Patent Application Publication
(10) Pub. No.: US 2026/0123024 A1
(43) Pub. Date: Apr. 30, 2026

(54) AIR GAPS FOR REDUCING CAPACITANCE IN CFETS

(71) Applicant: Taiwan Semiconductor Manufacturing Co, Ltd., Hsinchu (TW)

(72) Inventors: Shih-Jung Ho, Hsinchu (TW); Kuan-Kan Hu, Hsinchu (TW); Hsin Yang Hung, New Taipei City (TW); Rui-Fu Chen, Hsinchu (TW); Ku-Feng Yang, Baoshan Township (TW); Szuya Liao, Zhubei (TW)

(21) Appl. No.: 19/047,851

(22) Filed: Feb. 7, 2025

Related U.S. Application Data
(60) Provisional application No. 63/711,769, filed on Oct. 25, 2024.

(51) Int. Cl. H10D 84/01; H10D 64/23; H10D 84/85

(52) U.S. Cl. CPC H10D 84/0186; H10D 64/254; H10D 64/256; H10D 84/0188; H10D 84/851; H10D 84/856

(57) ABSTRACT

A method includes forming a lower source/drain region, forming a first contact etch stop layer and a first inter-layer dielectric over the first contact etch stop layer, forming an upper source/drain region over the first inter-layer dielectric and forming a second contact etch stop layer and a second inter-layer dielectric over the second contact etch stop layer. The upper source/drain region overlaps the lower source/drain region, The method further includes performing an etching process to form a trench in the first contact etch stop layer, the first inter-layer dielectric, the second contact etch stop layer, and the second inter-layer dielectric, forming a dummy liner in the trench, forming a dielectric liner in the trench, forming a contact plug in the trench and encircled by the dummy liner and the dielectric liner, and removing the dummy liner to form an air spacer. The air spacer encircles the contact plug.

### PRIORITY CLAIM AND CROSS-REFERENCE

This application claims the benefit of the following provisionally filed U.S. Patent application: Application No. 63/711,769, filed on Oct. 25, 2024, and entitled “AIR GAP IN VERTICAL INTERCONNECTION,” which application is hereby incorporated herein by reference.

### BACKGROUND

Semiconductor devices are used in a variety of electronic applications such as personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. As the minimum feature sizes are reduced, however, additional problems arise and should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 through FIGS. 11A, 11B, 11C, and 11D are views of intermediate stages in the formation of CFETs and contact plugs with air gaps in accordance with some embodiments.

FIG. 12 illustrates a cross-sectional view of CFETs and contact plugs with air gaps in accordance with alternatively embodiments.

FIGS. 13 and 14 are views of intermediate stages in the formation of CFETs and contact plugs with air gaps in accordance with alternative embodiments.

FIGS. 15A, 15B, and 15C illustrate the combinations of dielectric liners and air spacers in accordance with some embodiments.

FIG. 16 illustrates a flow chart for forming CFETs and contact plugs with air gaps in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Complementary Field-Effect Transistors (CFETs), contact plugs connected to the CFETs, air gaps, and the method of forming the same are provided. In accordance with some embodiments of the present disclosure, air gaps are formed to encircle contact plugs, so that the parasitic capacitance between the contact plugs and neighboring conductive features may be reduced.

It is appreciated that while Gate-All-Around (GAA) transistors (such as nanostructure-FETs) are discussed, the concept of the present disclosure can also be applied to the formation of contact plugs connecting to other types of transistors such as planar transistors, Fin Field-Effect Transistors (FinFETs), and the like. Throughout the description, the terms “FET” and “transistor” are used interchangeably.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

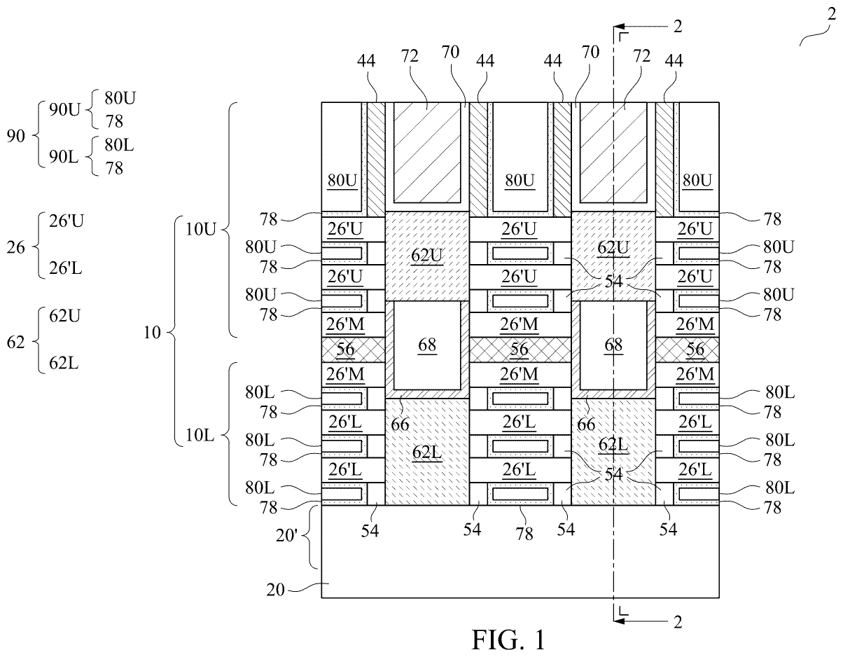

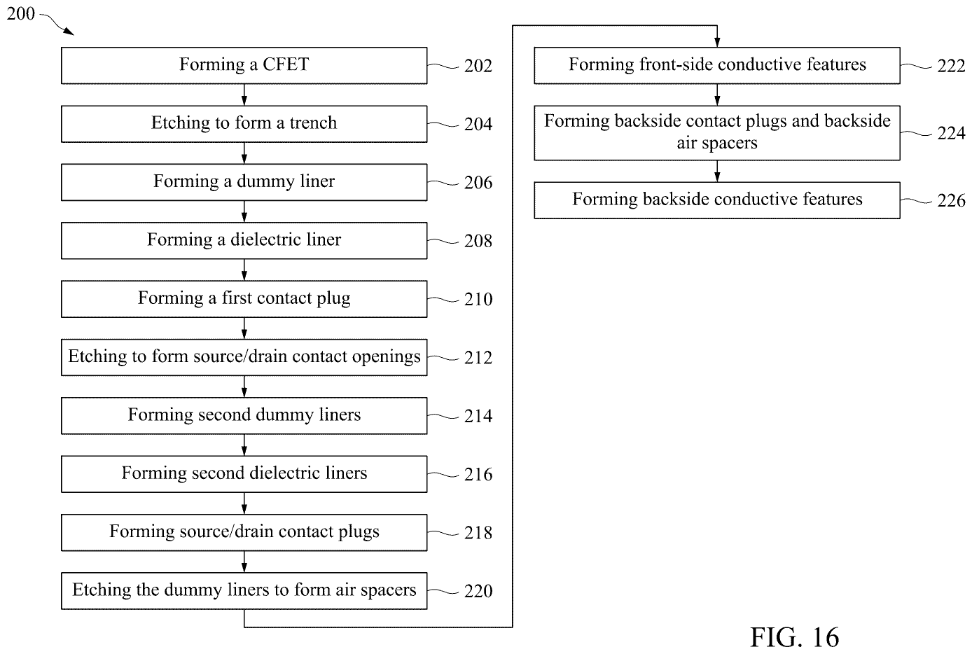

FIG. 1 through FIGS. 11A, 11B, 11C, and 11D illustrate the cross-sectional views of intermediate stages in the formation of CFETs, contact plugs, and corresponding air gaps in accordance with some embodiments of the present disclosure. The corresponding processes are also reflected schematically in the process flow shown in FIG. 16.

FIG. 1 illustrates the formation of an example CFET 10 (including FETs (transistors) 10U and 10L) in accordance with some embodiments. The respective process is illustrated as process 202 in the process flow 200 as shown in FIG. 16. CFET 10 may include a lower nanostructure-FET 10L of a first device type (e.g., n-type/p-type) and an upper nanostructure-FET 10U of a second device type (e.g., p-type/n-type) that is opposite the first device type. The nanostructure-FETs 10U and 10L include semiconductor nanostructures 26′ (including lower semiconductor nanostructures 26′L and upper semiconductor nanostructures 26′U), where the semiconductor nanostructures 26′ act as the channel regions for the nanostructure-FETs. The lower semiconductor nanostructures 26′L are for the lower nanostructure-FET 10L, and the upper semiconductor nanostructures 26′U are for the upper nanostructure-FET 10U.

As shown in FIG. 1, wafer 2, which includes substrate 20, is provided. Substrate 20 may be a semiconductor substrate, such as a bulk semiconductor, a semiconductor-on-insulator (SOI) substrate, or the like, which may be doped (e.g., with a p-type or an n-type dopant) or undoped. The SOI substrate may include a layer of a semiconductor material formed on an insulator layer. The insulator layer may be, for example, a buried oxide (BOX) layer, a silicon oxide layer, or the like. The insulator layer is provided on a substrate, such as a silicon or glass substrate. Other substrates, such as a multilayered or gradient substrate may also be used. In some embodiments, the semiconductor material of the substrate 20 may include silicon, germanium, carbon-doped silicon, a III-V compound semiconductor, or the like, or combinations thereof.

In the illustrated example, each of the upper FET 10U and lower FET 10L includes two semiconductor layers 26′U and 26′L, respectively, as the channels. It should be appreciated that the upper FET 10U and lower FET 10L may include any number of channel regions such as 1, 2, 3, or more. The portions of the gate stack 90 that are overlying and/or underlying the channel regions 26 form multilayer stacks with the corresponding channel regions 26′U and 26′L.

Gate stacks 90 (including upper gate stacks 90U and lower gate stacks 90L) are formed between semiconductor layers 26. Upper gate stacks 90U includes gate dielectrics 78 and upper gate electrodes 80U. Lower gate stacks 90L includes gate dielectrics 78 and lower gate electrodes 80L. Gate dielectrics 78 encircle (when viewed in side views) the respective semiconductor nanostructures 26. Gate electrodes 80 (including a lower gate electrode 80L and an upper gate electrode 80U) are over the gate dielectrics 78. Dielectric isolation layers 56 are formed to isolate the gate stack 90U of the upper FETs 10U from the gate stack 90L of the lower FETs 10L. Dummy semiconductor layers 26′M may be formed to contact dielectric isolation layers 56.

Source/drain regions 62 (including lower source/drain regions 62L and upper source/drain regions 62U) are disposed on opposing sides of the gate dielectrics 78 and the respective gate electrodes 80. The source/drain region may refer to a source or a drain, individually or collectively dependent upon the context.

Inner spacers 54, which are dielectric spacers, are formed on the opposing sides of the portions of gate stacks 90, which portions are between semiconductor layers 26. Inner spacers 54 electrically insulate the source/drain regions 62L and 62U from the corresponding parts of gate stacks 90 to prevent and reduce leakage.

Gate spacers 44 are formed over the multilayer stacks and on the sidewalls of gate stacks 90. The gate spacers 44 may be formed by conformally forming one or more dielectric layers and subsequently etching the dielectric layers anisotropically. The applicable dielectric materials may include silicon oxide, silicon nitride, silicon oxynitride, silicon oxycarbonitride, or the like, which may be formed by a deposition process such as Chemical Vapor Deposition (CVD), Atomic Layer Deposition (ALD), or the like.

Source/drain regions 62L and 62U are formed laterally between the multilayer stacks that comprise channel regions 26 and gate stacks 90. Lower source/drain regions 62L are formed over and contacting a substrate, which includes semiconductor substrate 20. The lower source/drain regions 62L are further in contact with the lower semiconductor nanostructures 26′L and are not in contact with the upper semiconductor nanostructures 26′U.

The lower source/drain regions 62L are epitaxially grown, and have a conductivity type that is suitable for the device type (p-type or n-type) of the lower nanostructure-FETs. When lower source/drain regions 62L are n-type source/drain regions, the respective material may include silicon or carbon-doped silicon, which is doped with an n-type dopant such as phosphorous, arsenic, or the like. When lower source/drain regions 62L are p-type source/drain regions, the respective material may include silicon or silicon germanium, which is doped with a p-type dopant such as boron, indium, or the like. The lower source/drain regions 62L may be in-situ doped, and may be, or may not be, implanted with the corresponding p-type or n-type dopants

A first contact etch stop layer (CESL) 66 and a first ILD 68 are formed over the lower source/drain regions 62L. The applicable dielectric material of the first ILD 68 may include phospho-silicate glass (PSG), boro-silicate glass (BSG), boron-doped phospho-silicate glass (BPSG), undoped silicate glass (USG), silicon oxide, or the like. The first CESL 66 may be formed of a dielectric material having a high etching selectivity from the etching of the first ILD 68. For example, the first CESL 66 may comprise silicon nitride, silicon oxide, silicon oxynitride, or the like, which may be formed by any suitable deposition process, such as CVD, ALD, or the like.

Upper source/drain regions 62U are formed overlapping the first CESL 66 and the first ILD 68, and overlapping the lower source/drain regions 62L. The materials of upper source/drain regions 62U may be selected from the same candidate group of materials for forming lower source/drain regions 62L, depending on the desired conductivity type of upper source/drain regions 62U.

The conductivity type of the upper source/drain regions 62U may be opposite the conductivity type of the lower source/drain regions 62L. Alternatively stated, the upper source/drain regions 62U may be oppositely doped than the lower source/drain regions 62L. The upper source/drain regions 62U may be in-situ doped, and/or may be implanted, with an n-type or p-type dopant.

A second CESL 70 and a second ILD 72 are formed over the upper source/drain regions 62U. The materials may be similar to, and may be the same as or different from, the materials and the formation methods of the first CESL 66 and first ILD 68, respectively, and are not discussed in detail herein.

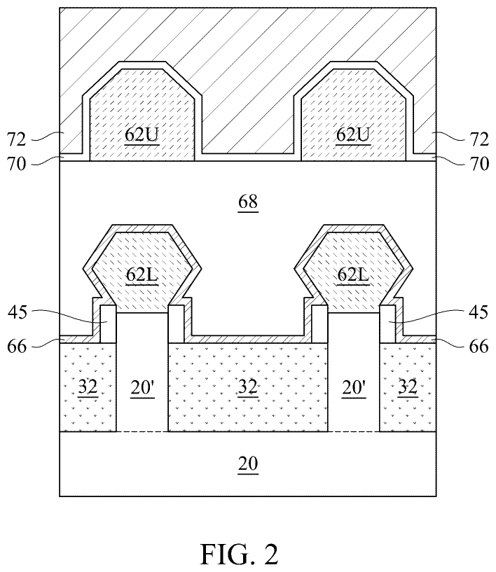

FIG. 2 illustrates a cross-sectional view of the structure as shown in FIG. 1. The illustrated cross-section may be the cross-section 2-2 as in FIG. 1. Dielectric isolation regions 32, also sometimes referred to as Shallow Trench Isolation (STI) regions 32, are formed over substrate 20. Semiconductor strips 20′ (also refer to FIG. 1) are formed between the STI regions 32. Fin spacers 45 may be formed on the sidewalls of the top portions of semiconductor strips 20′. Lower source/drain regions 62L, the first CESL 66, the first ILD 68, the upper source/drain regions 62U, the second CESL 70, and the second ILD 72 are illustrated. In accordance with some embodiments, the height of the lower source/drain regions 62L is greater than the height of the upper source/drain regions 62U. In accordance with alternative embodiments, the height of the lower source/drain regions 62L may be smaller than or equal to the height of the upper source/drain regions 62U.

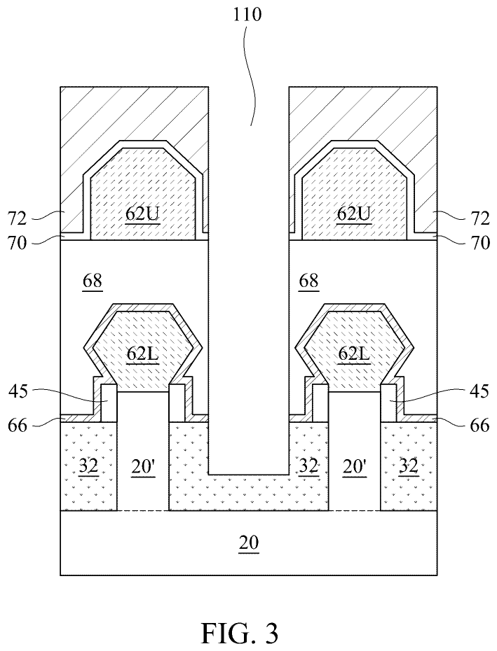

Referring to FIG. 3, an etching process is performed to etch the second ILD 72, the second CESL 70, the first ILD 68, and the first CESL 66, so that trench 110 (also referred to as contact opening 110) is formed. The respective process is illustrated as process 204 in the process flow 200 as shown in FIG. 16. Trench 110 may extend to an intermediate level between the top surface and the bottom surface of isolation region 32. Trench 110 may be formed between two neighboring upper source/drain regions 62U, and may be laterally spaced apart from the upper source/drain regions 62U by portions of the second CESL 70, and apart from the neighboring lower source/drain regions 62L by portions of the first CESL 66.

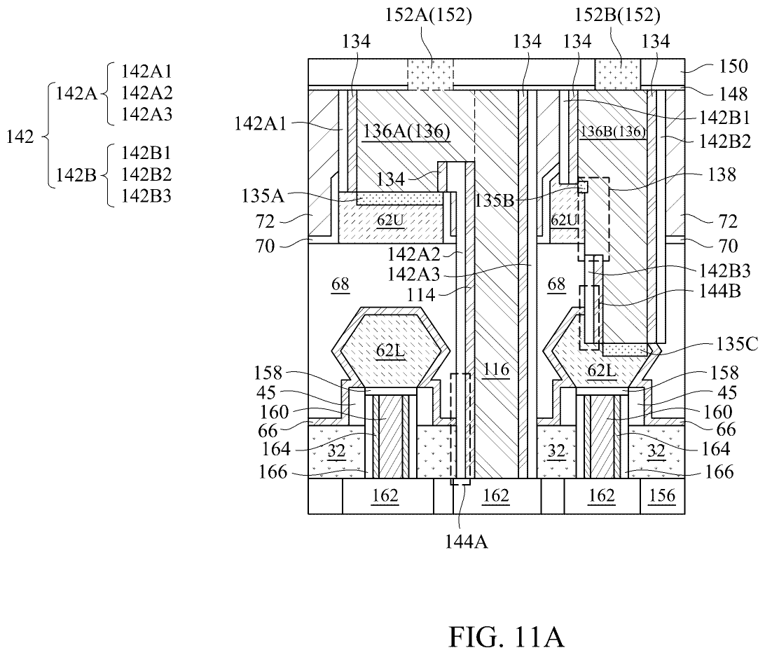

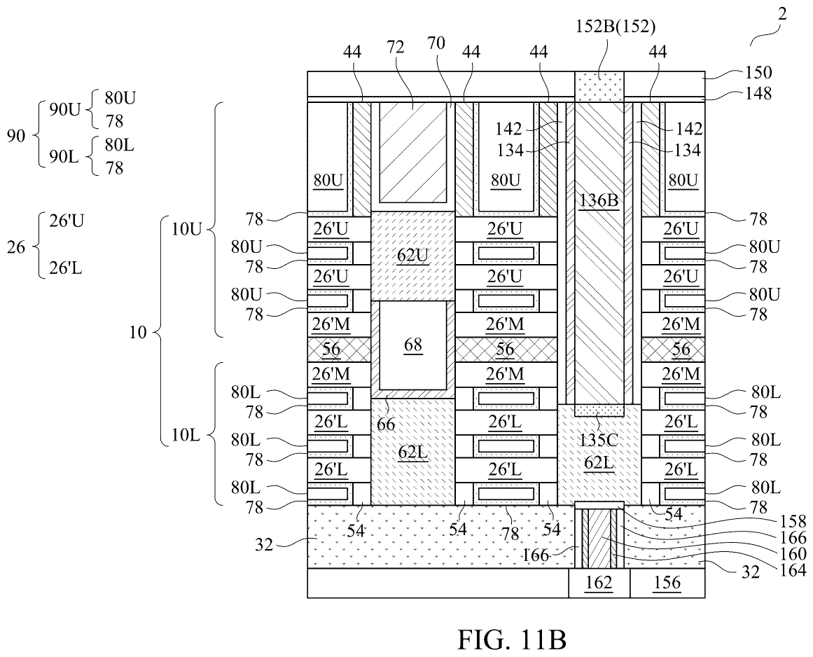

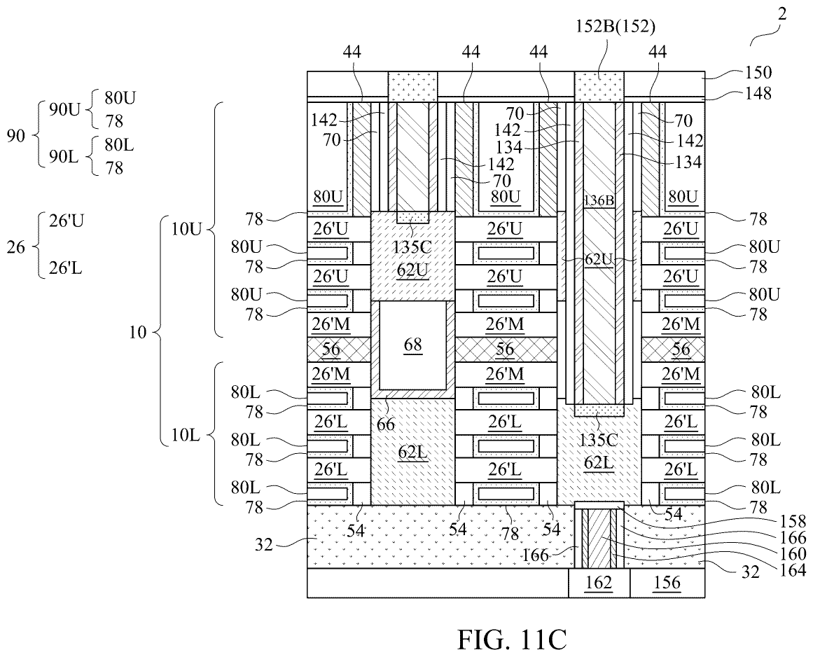

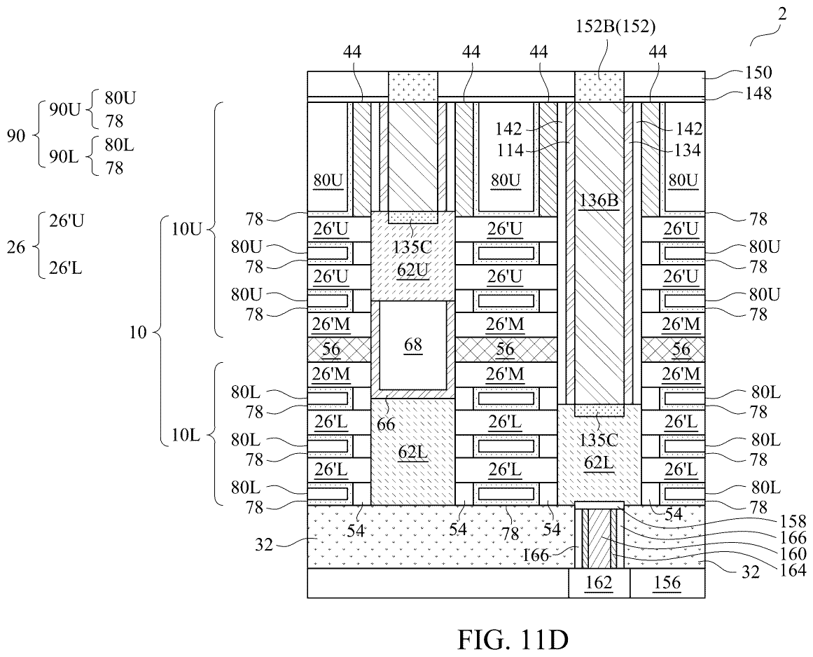

Trench 110 may also cut through gate stacks 90U and 90L (FIG. 1), which are not in the illustrated cross-section in FIG. 2. Accordingly, trench 110 and the dielectric liners (FIG. 11) and air gaps formed therein in subsequent processes may act as the gate isolation region that cuts long gate stacks into shorter gate stacks.

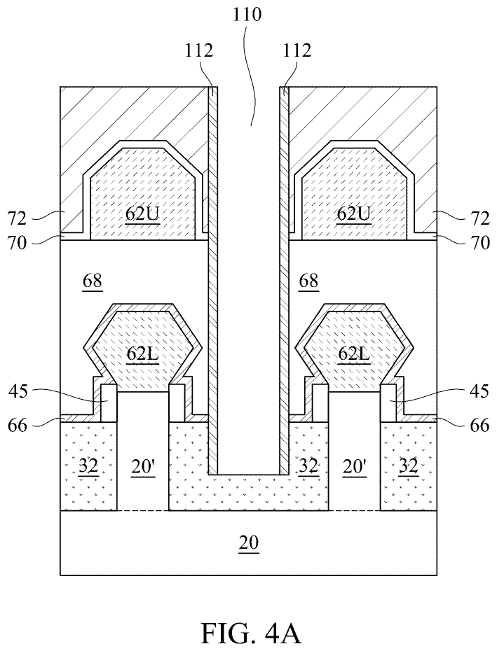

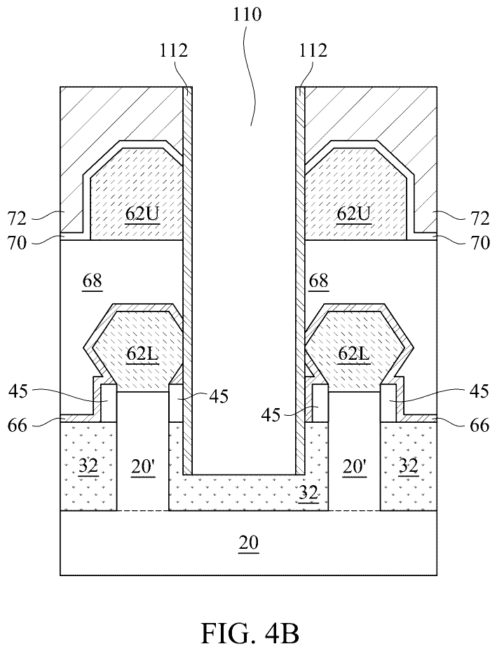

Referring to FIG. 4A, dummy liner 112 is formed in trench 110. The respective process is illustrated as process 206 in the process flow 200 as shown in FIG. 16. Dummy liner 112 is in contact with the sidewalls of the first CESL 66, the first ILD 68, the second CESL 70, and the second ILD 72. Dummy liner 112 may also be referred to as a sacrificial liner hereinafter. In the embodiments in FIG. 4A, dummy liner 112 is spaced apart from CESL 66 and fin spacer 45. In accordance with alternative embodiments as shown in FIG. 4B, the trench 110 may be formed larger, and the corner portion formed by joined facets of CESL 66 may be etched. Accordingly, lower source/drain region 62L, upper source/drain region 62U, and/or fin spacers 45 may be exposed to the trench 110. Also, dummy liner 112 may be in contact with fin spacer 45, lower source/drain region 62L, and/or upper source/drain region 62U.

In accordance with some embodiments, the formation of dummy liner 112 includes a conformal deposition process such as Chemical Vapor Deposition (CVD), Atomic Layer Deposition (ALD), Physical Vapor Deposition (PVD), or the like to form a conformal dielectric layer. In accordance with some embodiments, the material of dummy liner 112 may include amorphous Si, amorphous Ge, amorphous silicon germanium, amorphous carbon, a metal oxide of a metal such as Hf, Ti, Al, W, Nb, Re, or the like, a metal nitride of a metal such as Hf, Ti, Al, W, Nb, Re, or the like, or combinations thereof. Dummy liner 112 may have a single layer structure or a multi-layer structure including a plurality of sub layers formed of different materials.

After the deposition of the conformal dielectric layer, an anisotropic etching process is performed, so that the horizontal portions of the conformal dielectric layer are removed, and the vertical portions of the dielectric conformal layer inside trench 110 are left to form dummy liner 112. Dummy liner 112 may form a ring encircling trench 110 when viewed from the top of wafer 2.

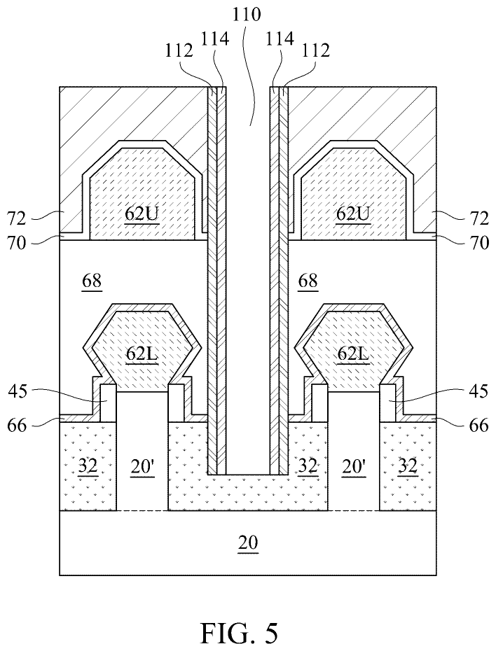

Referring to FIG. 5, dielectric liner 114 is formed. The respective process is illustrated as process 208 in the process flow 200 as shown in FIG. 16. Dielectric liner 114 is encircled by dummy liner 112. In accordance with some embodiments, the formation of dielectric liner 114 includes a conformal deposition process such as CVD, ALD, PVD, or the like to form a conformal dielectric layer. In accordance with some embodiments, the material of dielectric liner 114 may include silicon nitride, a metal oxide of a metal such as Hf, Ti, Al, W, Nb, Re, or the like, a metal nitride of a metal such as Hf, Ti, Al, W, Nb, Re, or the like, or combinations thereof. The material of dielectric liner 114 is also selected to be different from the material of dummy liner 112, so that in the subsequent removal of the dummy liner 112 for forming air gaps, dielectric liner 114 is not damaged.

After the deposition of the conformal dielectric layer, an anisotropic etching process is performed, so that the horizontal portions of the conformal dielectric layer are removed, and the vertical portions of the dielectric conformal layer inside trench 110 are left to form dielectric liner 114. Dielectric liner 114 may also form a ring encircling trench 110 when viewed from the top of wafer 2.

In above-discussed embodiments, an anisotropic etching process is performed after the deposition process of each of the dummy liner 112 and dielectric liner 114. Accordingly, both of the dummy liner 112 and dielectric liner 114 extend to the bottom of trench 110. In accordance with alternative embodiments, no anisotropic etching process is performed after the deposition of dummy liner 112, and an anisotropic etching is performed after the formation of dielectric liner 114 to pattern both of the conformal layers of the dummy liner 112 and dielectric liner 114.

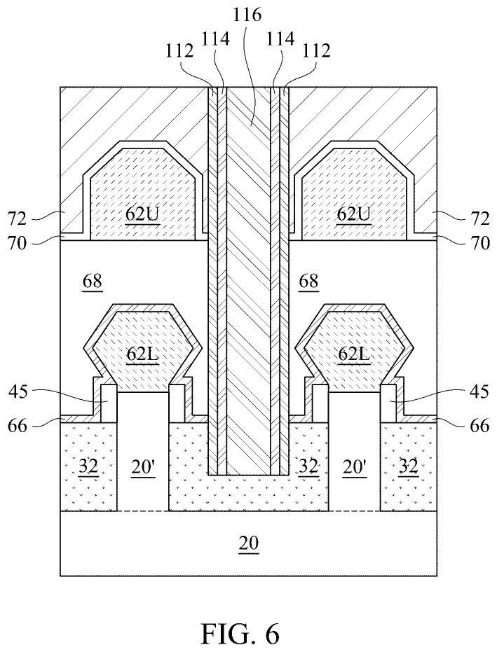

Referring to FIG. 6, contact plug 116 is formed. The respective process is illustrated as process 210 in the process flow 200 as shown in FIG. 16. Contact plug 116 may also be referred to as a vertical local interconnect. In accordance with some embodiments, contact plug 116 comprises a metal such as tungsten, molybdenum, ruthenium, iridium, or the like, or alloys thereof. In accordance with some embodiments, contact plug 116 has a single-layer structure, with the entire contact plug 116 formed of a homogeneous material such as aforementioned.

In accordance with alternative embodiments, the formation of contact plug 116 may include forming a barrier layer, which may comprise titanium, titanium nitride, tantalum, tantalum nitride, or the like. Next, a metallic material is deposited over and in contact with the barrier layer. The metallic material may include tungsten, cobalt, copper, nickel, molybdenum, ruthenium, iridium, or the like, or a combination thereof.

Further referring to FIG. 6, after the deposition of the material for forming contact plug 116, a planarization process such as a CMP process or a mechanical grinding process is performed to remove excess portions of the deposited material(s), leaving contact plug 116. The contact plug 116 is thus encircled by the dielectric liner 114, which is further encircled by dummy liner 112. The top surfaces of contact plug 116, dummy liner 112, and dielectric liner 114 are thus coplanar, and may further be coplanar with the top surface of the second ILD 72 when the second ILD 72 is the top layer in the structure.

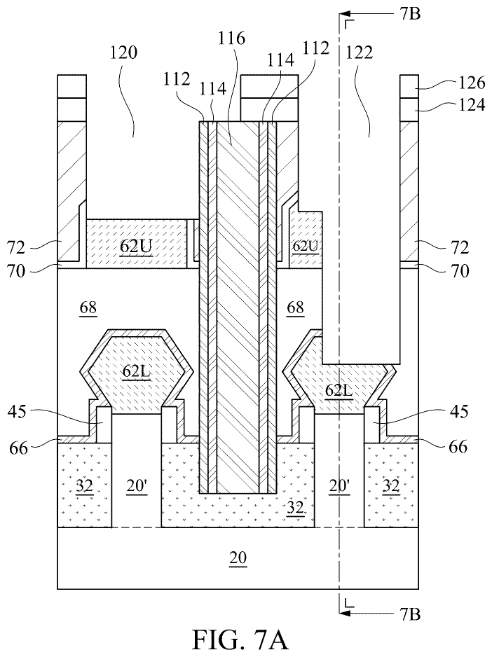

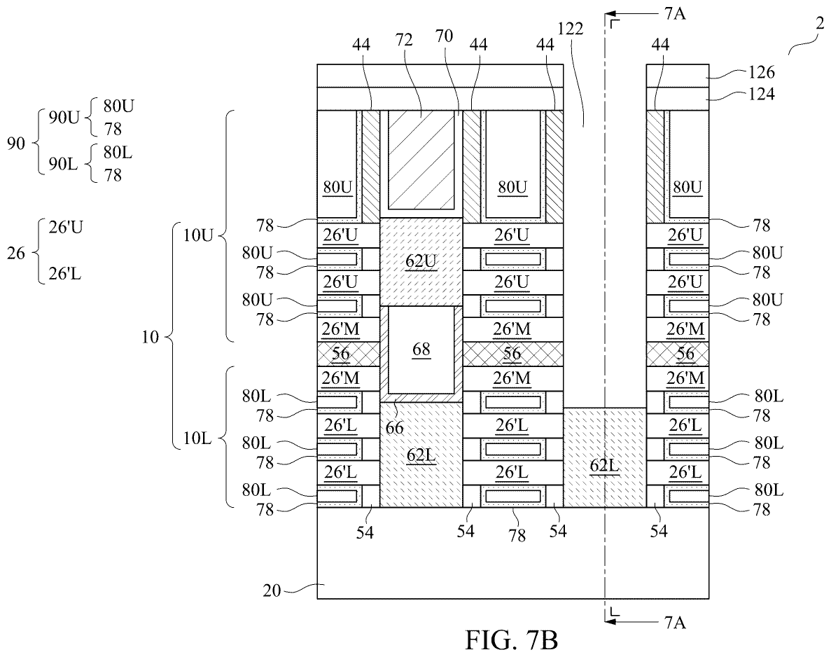

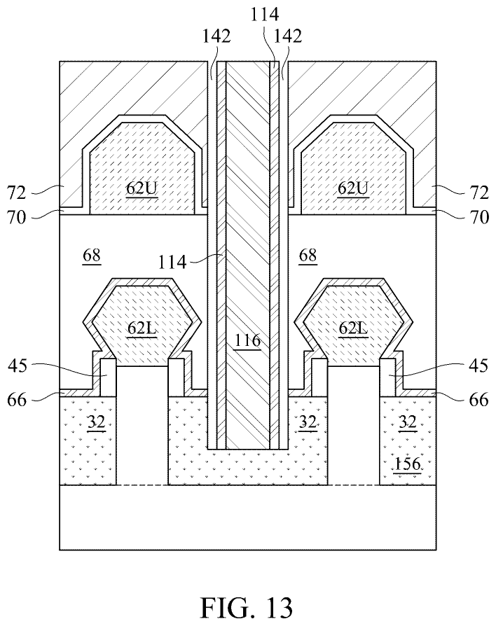

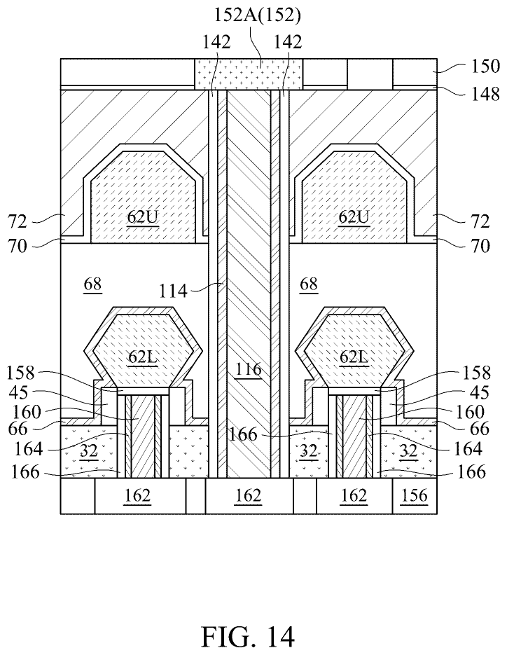

In accordance with some embodiments, after the formation of contact plug 116, the dummy liner 112 is removed to form an air spacer. The corresponding process is illustrated in FIGS. 13 and 14, which are discussed in detail in subsequent paragraphs. In accordance with alternative embodiments, instead of forming an air spacer now, the processes as shown in FIGS. 7A and 7B through FIGS. 11A, 11B, 11C, and 11D are performed.

FIGS. 7A and 7B illustrate the cross-sectional view of the formation of source/drain contact openings 120 and 122 in accordance with some embodiments. The respective process is illustrated as process 212 in the process flow 200 as shown in FIG. 16. The cross-sectional view as shown in FIG. 7A is obtained from the cross-section 7A-7A in FIG. 7B, and the cross-sectional view as shown in FIG. 7B is obtained from the cross-section 7B-7B in FIG. 7A.

In accordance with some embodiments, hard mask 124 is deposited. The hard mask 124 may be formed of or comprise TiN, BN, or the like. A patterned etching mask 126 is formed over hard mask 124, and is patterned. The patterned etching mask 126 may comprise a photoresist, and may comprise a bottom anti-reflective coating (BARC).

Hard mask 124 is then patterned through etching using the patterned etching mask 126 to define patterns. Contact openings 120 and 122 are thus formed. In the etching process, the underlying second ILD 72, second CESL 70, contact plug 116, dielectric liner 114, and dummy liner 112 are exposed. The second ILD 72 and the second CESL 70 are etched, so that the upper source/drain regions 62U are exposed. On the illustrated right side of the contact plug 116, some parts of the upper source/drain regions 62U are etched-through, followed by the etching of the underlying first ILD 68, first CESL 66. The etching stops on the top surface of the lower epitaxy source/drain region 62L. Some top surfaces of the upper epitaxy source/drain region 62U may also be exposed. For example, on the left side of the illustrated contact plug 116, the contact opening 120 stops on the top surface of one of upper source/drain regions 62U.

While one etching mask 126 is illustrated, the etching may be performed through one or more etching mask to achieve the desirable pattern. For example, one etching mask may be used to etch-through the upper source/drain region 62U, with the etching stopping on the lower source/drain region 62L. Another etching mask may be used to etch some portions of the second ILD 72 and second CESL 70 so that the top surfaces of some portions of the upper source/drain region 62U are exposed.

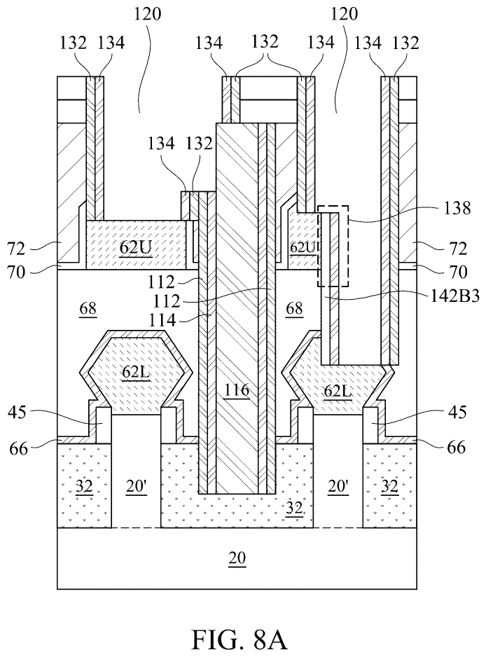

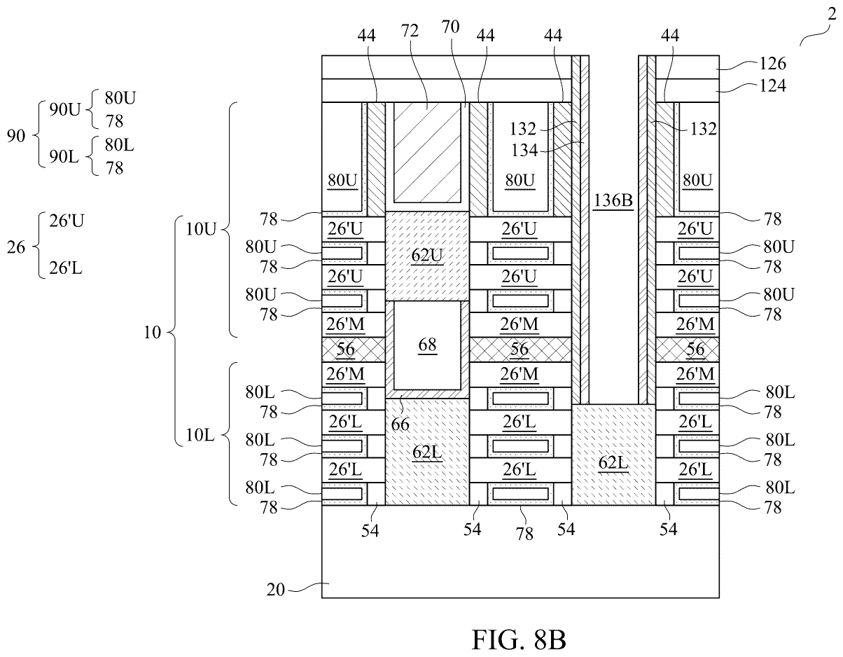

Referring to FIGS. 8A and 8B, dummy liners 132 are formed. The respective process is illustrated as process 214 in the process flow 200 as shown in FIG. 16. In accordance with some embodiments, the formation of dummy liners 132 includes depositing a first conformal layer through a first conformal deposition process, for example through ALD, CVD, PVD, or the like. An anisotropic etching process is then performed to remove the horizontal portion of the first conformal layer, leaving the vertical portions as the dummy liners 132. The material of the dummy liner 132 may be selected from the same group of candidate materials for forming dummy liner 112, and may be the same as or different from the material of dummy liner 112.

Dielectric liners 134 are then formed. The respective process is illustrated as process 216 in the process flow 200 as shown in FIG. 16. In accordance with some embodiments, the formation of dielectric liners 134 includes depositing a second conformal layer through a second conformal deposition process, for example through ALD, CVD, PVD, or the like. An anisotropic etching process is then performed to remove the horizontal portion of the second conformal layer, leaving the vertical portions as the dielectric liners 134. The material of the dielectric liners 134 may be selected from the same group of candidate materials for forming dielectric liner 114, and may be the same as or different from the material of dielectric liner 114.

In accordance with some embodiments, due to the anisotropic etching for forming dummy liners 132 and dielectric liners 134, the exposed portions of dummy liner 112 and dielectric liner 114 on the sidewall of contact plug 116 may be recessed, as shown in FIG. 8A. In addition, recessing may also occur on the portions of dummy liner 132 and dielectric liner 134 in the dashed region 138. The recessing may be caused due to the cleaning processes that are performed before the formation of contact plugs. Accordingly, the portions of the dummy liner 132 and dielectric liner 134 in the dashed region 138 may or may not exist, and the sidewall of the upper epitaxy source/drain region 62U in contact opening 122 may be revealed to contact opening 122, or may remain to be protected by dummy liner 132 and dielectric liner 134 when dummy liner 132 and dielectric liner 134 are not recessed, and are left in region 138.

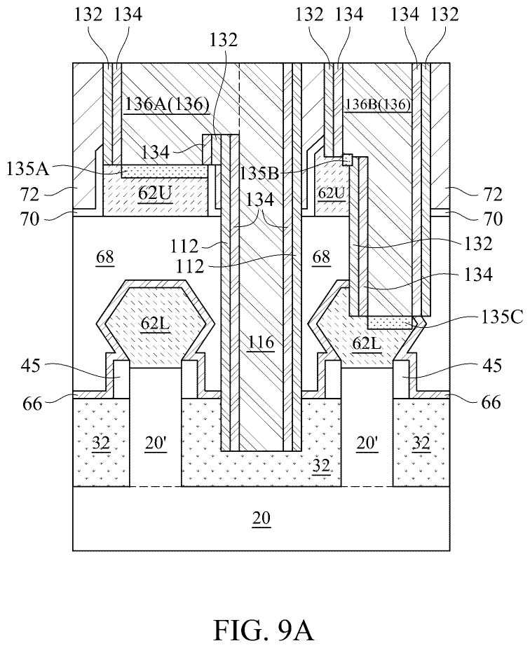

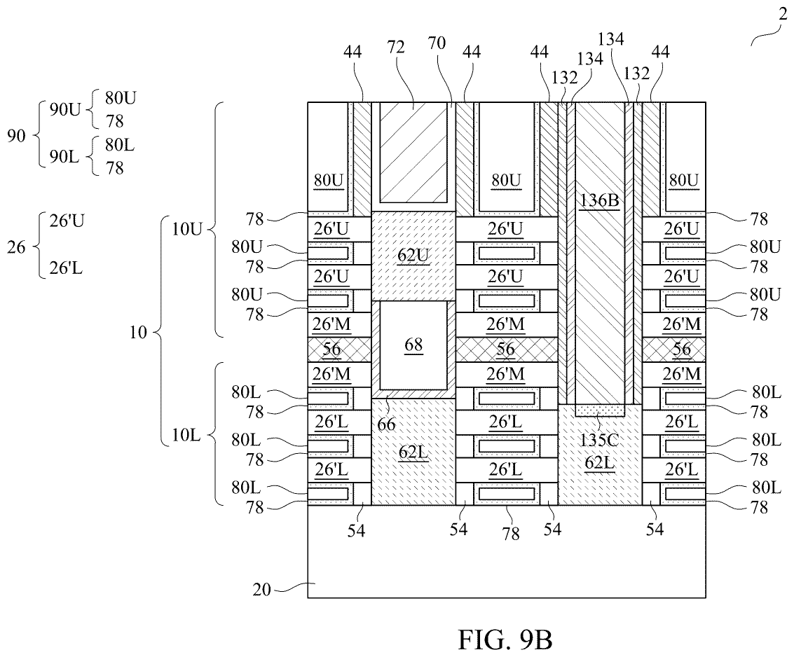

Referring to FIGS. 9A and 9B, silicide layers 135A and 135B are formed on the top surfaces of upper source/drain regions 62U, and silicide layer 135C is formed on the top surface of lower source/drain region 62L. The formation process may include depositing a metal layer (not shown), for example, using a conformal deposition process such as Physical Vapor Deposition (PVD). A barrier/capping layer (not shown), which may be a metal nitride layer such as a titanium nitride layer or a tantalum nitride layer, is then deposited over the metal layer.

An annealing process is then performed to react the metal layer with the silicon (and germanium, if any) in upper source/drain regions 62U and lower source/drain regions 62L. Source/drain silicide layers 135A, 135B, and 135C are thus formed. The annealing process may be performed through Rapid Thermal Anneal (RTA), furnace anneal, or the like. The barrier layer and the remaining metal layer may then be removed, for example, in an anisotropic etching process.

Next, contact plugs 136A and 136B are formed, which are individually and collectively referred to as contact plugs 136. The respective process is illustrated as process 218 in the process flow 200 as shown in FIG. 16. Contact plugs 136A and 136B may be referred to as source/drain contact plugs, and contact plug 136A may be referred to as an upper source/drain contact plug. In accordance with some embodiments, contact plugs 136A and 136B comprise a metal such as tungsten, molybdenum, ruthenium, iridium, or the like, or alloys thereof. In accordance with some embodiments, contact plugs 136A and 136B have a single-layer structure, with the entire contact plugs 136A and 136B being formed of a homogeneous material such as aforementioned.

In accordance with alternative embodiments, the formation of contact plugs 136A and 136B may include forming a barrier layer, which may comprise titanium, titanium nitride, tantalum, tantalum nitride, or the like. Next, a metallic material is deposited over and in contact with the barrier layer. The metallic material may include tungsten, cobalt, copper, nickel, molybdenum, ruthenium, iridium, or the like, or a combination thereof.

Further referring to FIGS. 9A and 9B, after the deposition of the material for forming contact plug 116, a planarization process such as a CMP process or a mechanical grinding process is performed to remove excess portions of the deposited material(s), leaving contact plugs 136A and 136B. The contact plugs 136A and 136B are thus encircled by the dielectric liners 134, which are further encircled by dummy liners 132. The top surfaces of contact plugs 136A and 136B, dummy liner 132, and dielectric liner 134 are thus coplanar, and may further be coplanar with the top surface of the second ILD 72.

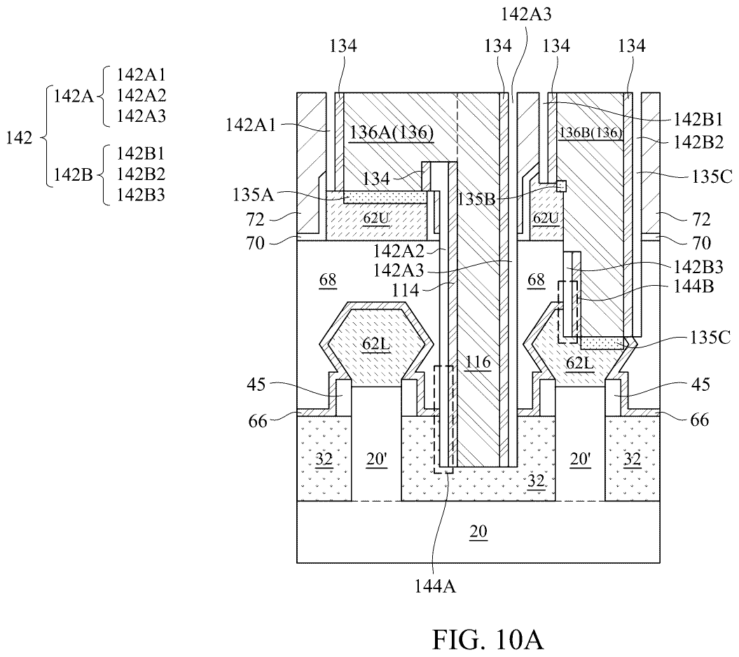

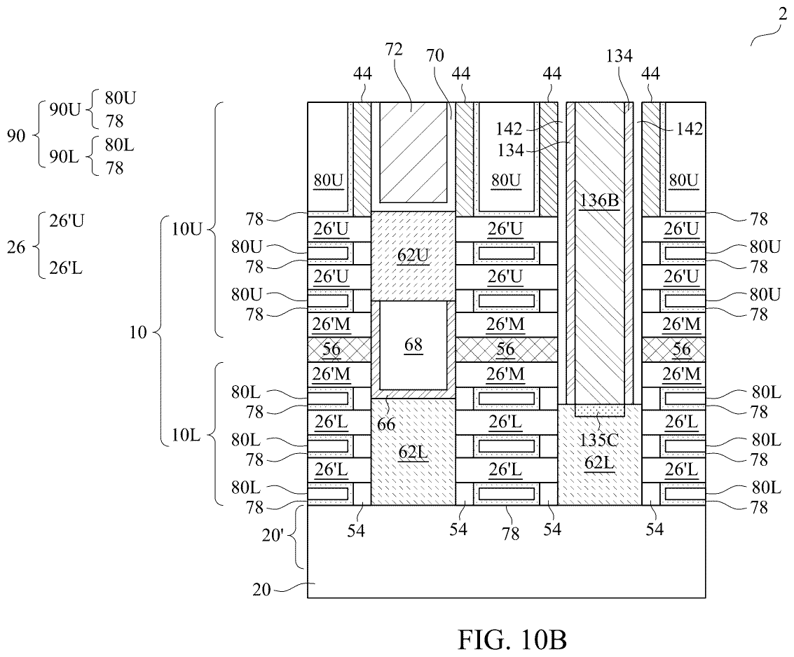

Referring to FIGS. 10A and 10B, dummy liners 112 and 132 are removed, forming air spacers 142, which includes air spacers 142A and 142B. The respective process is illustrated as process 220 in the process flow 200 as shown in FIG. 16. The removal may be performed through an isotropic etching process, and may be performed using a dry etching process and/or a wet etching process. The etching chemical (such as the etching gas or the etching chemical solution) is selected to be able to remove dummy liners 112 and 132, while other materials such as dielectric liners 114 and 134, the second ILD 72, the second CESL 70, the first ILD 68, the first CESL 66, the upper source/drain regions 62U, and the lower source/drain regions 62L are not etched.

Air spacer 142A may include portion 142A1, 142A2, and 142A3. It is appreciated that although in the illustrated cross-section, air spacer portions 142A1, 142A2, and 142A3 are separated from each other, since the dummy liners 112 and 132 are formed as having the top-view shapes of rings, air spacer portions 142A1, 142A2, and 142A3 may be parts of continuous ring-shaped air spacers, and the parts are interconnected through the portions of the air spacers in the un-illustrated planes.

Similarly, air spacer 142B may include portion 142B1, 142B2, and 142B3. It is appreciated that although in the illustrated cross-section, air spacer portions 142B1, 142B2, and 142B3 are separated from each other, since the original dummy liners 132 are formed as having the top-view shapes of rings, air spacer portions 142B1, 142B2, and 142B3 are also parts of continuous ring-shaped air spacers, and the parts are also interconnected through the portions of the air spacers in the un-illustrated planes.

Since the portions of dummy liners 112 and 132 in regions 144A and 144B are not directly connected to outside environment, the portions of dummy liners 112 and 132 in regions 144A and 144B may be removed after the air spacer portions 142A3 and 142B3 are removed, and the air spacers encroach toward regions 144A and 144B. Accordingly, in accordance with some embodiments, the portions of dummy liners 112 and 132 in regions 144A and 144B are fully removed. The air spacer portion 142A2 accordingly extends to isolation region 32, and the air spacer portion 142B3 extends to lower source/drain region 62L.

In accordance with alternative embodiments, the portions of dummy liners 112 and 132 in regions 144A and/or 144B are not removed, and some portions of dummy liners 112 and 132 are left in either one or both of regions 144A and 144B. Furthermore, since the etching is extended from top to bottom, the bottom portions of dummy liners 112 and 132 in either one or both of regions 144A and 144B may remain, while air spacers 142A2 and/or 142B3 are formed over the remaining dummy liners 112 and/or 132.

In accordance with some embodiments in which dummy liner 112 has a portion left in region 144A, in the illustrated cross-section, air spacer 142A2 is capped from top side by contact plug 136A, and is also blocked from bottom side by the remaining portion of dummy liner 112.

It is also appreciated that although air spacers/portions 142A1, 142A2, 142A3, 142B1, 142B2, and 142B3 are illustrated as examples in accordance with some embodiments, in other embodiments, one, more, or all of the air spacers/portions 142A1, 142A2, 142A3, 142B1, 142B2, and 142B3 may be formed in any combination whenever applicable. The resulting structures thus may include any one, two, three, four, five or more of the illustrated air spacers in any applicable combination.

Referring to FIGS. 11A and 11B, etch stop layer 148 and dielectric layer 150 are formed. Etch stop layer 148 may comprise AlN, AlO, SiOC, or the like, or multilayers thereof. Dielectric layer 150 may comprise silicon oxide, silicon nitride, silicon oxynitride, silicon carbide, or the like.

Front-side conductive features 152 (which may include conductive features 152A and 152B) such as metal lines or metal vias are then formed over and electrically coupled to upper source/drain contact plugs 136. The respective process is illustrated as process 222 in the process flow 200 as shown in FIG. 16. Conductive features 152 may comprise tungsten, cobalt, copper, aluminum, titanium, titanium nitride, tantalum, tantalum nitride, or the like, alloys thereof, and/or multilayers thereof.

In accordance with some embodiments, conductive feature 152A is formed. In accordance with alternative embodiments, conductive feature 152A is not formed, and currents may flow through an electrical path including contact plug 116, contact plug 136A, silicide layer 135A, and upper source/drain region 62U. Accordingly, upper source/drain region 62U is connected to the backside conductive features 162, and is not connected to any overlying conductive features. In these embodiments, the entireties of the top surface of contact plug 136A and 116 are in contact with etch stop layer 148.

FIGS. 11A, 11B, 11C, and 11D further illustrate the formation of backside source/drain contact plugs electrically connected to lower source/drain regions 62L, and the formation of backside redistribution lines. In accordance with some embodiments, substrate 20 (FIGS. 10A and 10B) is removed, for example, through a CMP process and/or an etching process(es). A dielectric substrate 156 (FIGS. 11A, 11B, 11C, and 11D) may be formed.

Semiconductor strips 20′ (FIGS. 10A and 10B) are etched to form backside openings, through which the bottoms of lower source/drain regions 62L are exposed. Silicide layers 158 are formed underlying and contacting the bottom surfaces of lower source/drain regions 62L. The materials and the formation processes of silicide layers 158 may be essentially the same as that of silicide layers 135A, 135B, and 135C, and are not repeated herein.

Backside contact plugs 160 are formed to fill the remaining backside contact openings. The respective process is illustrated as process 224 in the process flow 200 as shown in FIG. 16. Backside contact plugs 160 are in contact with silicide layers 158. Backside contact plugs 160 may be formed of a homogeneous metallic material, which may comprise tungsten, cobalt, ruthenium, or the like. Alternatively, the formation of backside contact plugs 160 may include forming a barrier layer, which may comprise titanium, titanium nitride, tantalum, tantalum nitride, or the like, and the homogeneous metallic material on the barrier layer. A planarization process such as a CMP process or a mechanical grinding process is then performed to remove excess portions of the deposited materials, leaving backside contact plugs 160.

Air spacers 166 are formed to encircle contact plugs 160. The respective process is also illustrated as process 224 in the process flow 200 as shown in FIG. 16. Dielectric liners 164 may also be formed to encircle contact plugs 160, and encircled by air spacers 166. The formation of air spacers 166 may be essentially the same as the formation of air spacers 142, and may include depositing dummy liners and dielectric liners 164, and removing the dummy lines after the planarization process for forming backside contact plugs 160.

Backside redistribution lines 162 (conductive features 162) are formed on the backside of CFETs, and are formed in dielectric layer 156. The respective process is illustrated as process 226 in the process flow 200 as shown in FIG. 16. Backside redistribution lines 162 are thus electrically connected to contact plug 116, and to lower source/drain region 62L.

FIG. 11C illustrates a structure in accordance with alternative embodiments. These embodiments are essentially the same as the structure shown in FIG. 11B, except an additional contact plug 136C is formed over the upper source/drain region 62U on the left side of FIG. 11B.

FIG. 11D illustrates a structure in accordance with alternative embodiments. These embodiments are essentially the same as the structure shown in FIG. 11B, except that an additional contact plug 136C is formed over the upper source/drain region 62U on the left side of FIG. 11B. Furthermore, the vertical portions of the second CESL 70 may remain, and are exposed to air gap 142. The upper source/drain region 62U on the right side of FIG. 11D may also have some portions left, and exposed to air gaps 142.

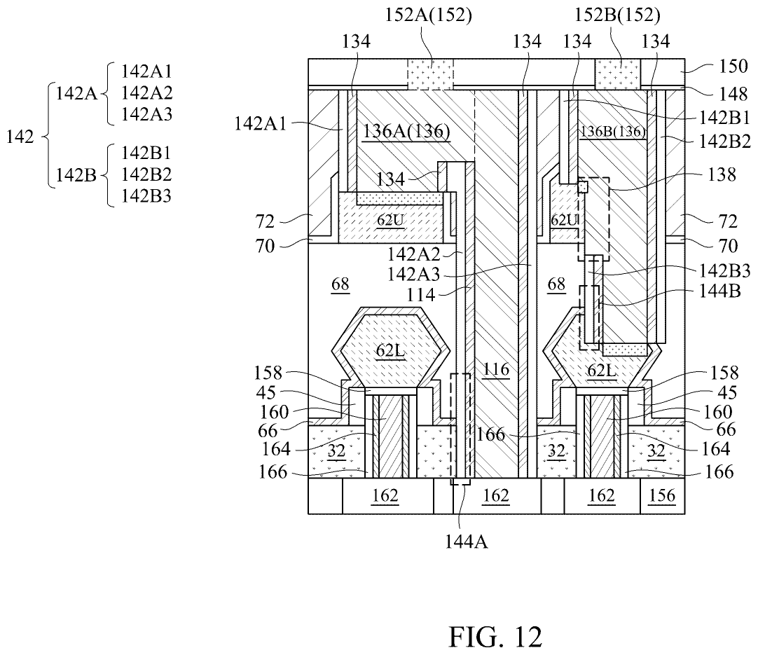

FIG. 12 illustrates a structure in accordance with alternative embodiments. These embodiments are essentially the same as that in FIG. 11A, except that contact plug 136B, rather than dielectric liner 134 and air spacer 142B3 (FIG. 11A), is formed in the region 138 in FIG. 12. This structure is formed due to the recessing and the removal of dummy liner 132 and dielectric liner 134 from region 138, as discussed referring to FIG. 8A.

FIGS. 13 and 14 illustrate the intermediate steps in the formation of a discrete contact plug 116 in accordance with alternative embodiments. The discrete contact plug 116 is not connected to (source/drain) contact plug 136A (FIG. 11A). The initial processes are essentially the same as that in FIGS. 1-6, and are not repeated herein.

Next, the dummy liner 112 as shown in FIG. 6 is removed in an etching process, and hence the structure shown in FIG. 13 is formed. In subsequent processes, conductive features 152 and 162 are formed on the front side and the backside of the contact plug 116, as shown in FIG. 14.

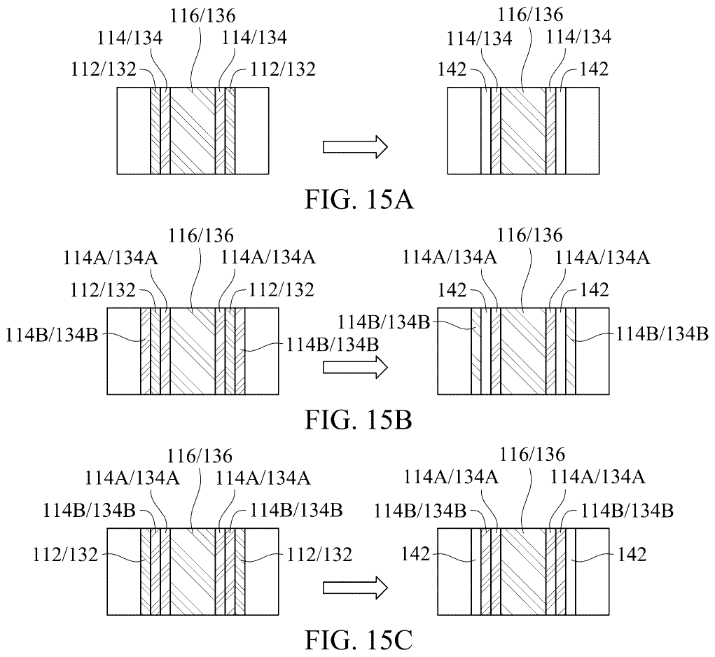

In above-discussed example processes, one dielectric liner 114/134 (including dielectric liners 114 and/or 134) is formed, and dummy liner 112/132 (including dummy liners 112 and/or 132) and the resulting air spacer 142 are formed encircling the corresponding dielectric liner 114/134. In accordance with alternative embodiments, there may be any number (such as 2, 3, or more) of dielectric liners, and the air spacers may be formed in any position relative to the dielectric liners. For example, FIG. 15A illustrates the formation of a structure shown in preceding embodiments, in which the dummy liner 112/132 is formed to encircle dielectric liner 114/134, and the dummy liner 112/132 is removed to form air spacer 142.

FIG. 15B illustrates the formation of the dummy liner 112/132 and the resulting air spacer 142 are formed between two dielectric liners 114A/134A and 114B/134B. Accordingly, air spacers 142 are also formed between dielectric liners 114A/134A and 114B/134B. FIG. 15C illustrates the formation of the dummy liner 112/132 and the resulting air spacer 142 encircling two dielectric liners 114A/134A and 114B/134B.

The embodiments of the present disclosure have some advantageous features. By forming air spacers, parasitic capacitance between conductive features may be reduced.

In accordance with some embodiments of the present disclosure, a method comprises forming a lower source/drain region; forming a first contact etch stop layer over the lower source/drain region; forming a first inter-layer dielectric over the first contact etch stop layer; forming a upper source/drain region over the first inter-layer dielectric, wherein the upper source/drain region overlaps the lower source/drain region; forming a second contact etch stop layer over the upper source/drain region; forming a second inter-layer dielectric over the second contact etch stop layer; performing an etching process to form a trench in the first contact etch stop layer, the first inter-layer dielectric, the second contact etch stop layer, and the second inter-layer dielectric; forming a first dummy liner in the trench; forming a first dielectric liner in the trench; forming a contact plug in the trench and encircled by the first dummy liner and the first dielectric liner; and removing the first dummy liner to form a first air spacer, wherein the first air spacer encircles the contact plug.

In an embodiment, the method further comprises forming a silicide layer over the upper source/drain region; and forming an upper source/drain contact plug over and electrically connected to the upper source/drain region through the silicide layer, wherein the upper source/drain contact plug physically contacts the contact plug. In an embodiment, the forming the upper source/drain contact plug comprises: etching the second inter-layer dielectric and the second contact etch stop layer to form a source/drain contact opening; forming a second dummy liner in the source/drain contact opening; forming a second dielectric liner in the source/drain contact opening, wherein the upper source/drain contact plug is formed in the source/drain contact opening; and removing the second dummy liner to form a second air spacer.

In an embodiment, the forming the first dummy liner and the forming the second dummy liner are performed in separate formation processes. In an embodiment, the removing the first dummy liner and the removing the second dummy liner are performed through a same etching process. In an embodiment, the method further comprises forming a bottom conductive feature underlying and electrically connected to the contact plug.

In an embodiment, the method further comprises forming a bottom conductive feature underlying and electrically connected to the lower source/drain region, wherein an additional air spacer is formed to encircle the bottom conductive feature. In an embodiment, the method further comprises forming an additional dielectric liner in the trench, wherein the first air spacer is formed between the first dielectric liner and the additional dielectric liner.

In accordance with some embodiments of the present disclosure, a method comprises forming a lower source/drain region; forming an upper source/drain region overlapping the lower source/drain region; performing a first etching process to form a first contact opening extending from a first level higher than the upper source/drain region to a second level lower than the lower source/drain region; forming a first dummy liner and a first dielectric liner in the first contact opening; forming a first contact plug encircled by the first dummy liner and the first dielectric liner; performing a second etching process to form a second contact opening extending from the first level to a top surface of the upper source/drain region; forming a second dummy liner and a second dielectric liner in the second contact opening; forming a second contact plug encircled by the second dummy liner and the second dielectric liner, wherein the second contact plug is electrically connected to the first contact plug; and etching the first dummy liner and the second dummy liner to form a first air spacer and a second air spacer, respectively.

In an embodiment, the first dummy liner and the second dummy liner are formed in separate processes. In an embodiment, the first dummy liner and the second dummy liner are etched in a common etching process. In an embodiment, the first contact plug is in physical contact with the second contact plug. In an embodiment, when the second dummy liner and the second dielectric liner are formed, parts of the first dummy liner and the first dielectric liner are exposed to the second contact opening.

In an embodiment, when the second dummy liner and the second dielectric liner are formed, the parts of the first dummy liner and the first dielectric liner are recessed. In an embodiment, after the second dummy liner and the second dielectric liner are formed, portions of the second dummy liner are in contact with the parts of the first dummy liner that are recessed. In an embodiment, when the first dummy liner and the second dummy liner are etched, a portion of the first dummy liner is covered by the second contact plug.

In accordance with some embodiments of the present disclosure, a structure comprises a lower source/drain region; a first contact etch stop layer over the lower source/drain region; a first inter-layer dielectric over the first contact etch stop layer; an upper source/drain region over the first inter-layer dielectric, wherein the upper source/drain region overlaps the lower source/drain region; a second contact etch stop layer over the upper source/drain region; a second inter-layer dielectric over the second contact etch stop layer; a contact plug aside of the lower source/drain region and the upper source/drain region; and an air spacer, wherein in a top view of the structure, the air spacer encircles at least a portion of the contact plug.

In an embodiment, in a cross-sectional view of the structure, the air spacer comprises: a first portion on a first side of the contact plug, wherein the first portion extends from a top surface level to a bottom surface level of the contact plug; and a second portion on a second side of the contact plug opposing the first side, wherein the second portion extends from an intermediate level to the top surface or the bottom surface of the contact plug. In an embodiment, on the second side of the contact plug and in the cross-sectional view, the air spacer is separated into two portions. In an embodiment, the two portions are separated from each other by a part of the contact plug.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a lower source/drain region;
forming a first contact etch stop layer over the lower source/drain region;
forming a first inter-layer dielectric over the first contact etch stop layer;
forming a upper source/drain region over the first inter-layer dielectric, wherein the upper source/drain region overlaps the lower source/drain region;
forming a second contact etch stop layer over the upper source/drain region;
forming a second inter-layer dielectric over the second contact etch stop layer;
performing an etching process to form a trench in the first contact etch stop layer, the first inter-layer dielectric, the second contact etch stop layer, and the second inter-layer dielectric;
forming a first dummy liner in the trench;
forming a first dielectric liner in the trench;
forming a contact plug in the trench and encircled by the first dummy liner and the first dielectric liner; and
removing the first dummy liner to form a first air spacer, wherein the first air spacer encircles the contact plug.

2. The method of claim 1 further comprising:
forming a silicide layer over the upper source/drain region; and
forming an upper source/drain contact plug over and electrically connected to the upper source/drain region through the silicide layer, wherein the upper source/drain contact plug physically contacts the contact plug.

3. The method of claim 2, wherein the forming the upper source/drain contact plug comprises:
etching the second inter-layer dielectric and the second contact etch stop layer to form a source/drain contact opening;
forming a second dummy liner in the source/drain contact opening;
forming a second dielectric liner in the source/drain contact opening, wherein the upper source/drain contact plug is formed in the source/drain contact opening; and
removing the second dummy liner to form a second air spacer.

4. The method of claim 3, wherein the forming the first dummy liner and the forming the second dummy liner are performed in separate formation processes.

5. The method of claim 4, wherein the removing the first dummy liner and the removing the second dummy liner are performed through a same etching process.

6. The method of claim 1 further comprising forming a bottom conductive feature underlying and electrically connected to the contact plug.

7. The method of claim 1 further comprising forming a bottom conductive feature underlying and electrically connected to the lower source/drain region, wherein an additional air spacer is formed to encircle the bottom conductive feature.

8. The method of claim 1 further comprising forming an additional dielectric liner in the trench, wherein the first air spacer is formed between the first dielectric liner and the additional dielectric liner.

9. A method comprising:
forming a lower source/drain region;
forming an upper source/drain region overlapping the lower source/drain region;
performing a first etching process to form a first contact opening extending from a first level higher than the upper source/drain region to a second level lower than the lower source/drain region;
forming a first dummy liner and a first dielectric liner in the first contact opening;
forming a first contact plug encircled by the first dummy liner and the first dielectric liner;
performing a second etching process to form a second contact opening extending from the first level to a top surface of the upper source/drain region;
forming a second dummy liner and a second dielectric liner in the second contact opening;
forming a second contact plug encircled by the second dummy liner and the second dielectric liner, wherein the second contact plug is electrically connected to the first contact plug; and
etching the first dummy liner and the second dummy liner to form a first air spacer and a second air spacer, respectively.

10. The method of claim 9, wherein the first dummy liner and the second dummy liner are formed in separate processes.

11. The method of claim 10, wherein the first dummy liner and the second dummy liner are etched in a common etching process.

12. The method of claim 9, wherein the first contact plug is in physical contact with the second contact plug.

13. The method of claim 9, wherein when the second dummy liner and the second dielectric liner are formed, parts of the first dummy liner and the first dielectric liner are exposed to the second contact opening.

14. The method of claim 13, wherein when the second dummy liner and the second dielectric liner are formed, the parts of the first dummy liner and the first dielectric liner are recessed.

15. The method of claim 14, wherein after the second dummy liner and the second dielectric liner are formed, portions of the second dummy liner are in contact with the parts of the first dummy liner that are recessed.

16. The method of claim 9, wherein when the first dummy liner and the second dummy liner are etched, a portion of the first dummy liner is covered by the second contact plug.

17. A structure comprising:
a lower source/drain region;
a first contact etch stop layer over the lower source/drain region;
a first inter-layer dielectric over the first contact etch stop layer;
an upper source/drain region over the first inter-layer dielectric, wherein the upper source/drain region overlaps the lower source/drain region;
a second contact etch stop layer over the upper source/drain region;
a second inter-layer dielectric over the second contact etch stop layer;
a contact plug aside of the lower source/drain region and the upper source/drain region; and
an air spacer, wherein in a top view of the structure, the air spacer encircles at least a portion of the contact plug.

18. The structure of claim 17, wherein in a cross-sectional view of the structure, the air spacer comprises:
a first portion on a first side of the contact plug, wherein the first portion extends from a top surface level to a bottom surface level of the contact plug; and
a second portion on a second side of the contact plug opposing the first side, wherein the second portion extends from an intermediate level to the top surface or the bottom surface of the contact plug.

19. The structure of claim 18, wherein on the second side of the contact plug and in the cross-sectional view, the air spacer is separated into two portions.

20. The structure of claim 19, wherein the two portions are separated from each other by a part of the contact plug.
